(19) United States
(12) Patent Application Publication
(10) Pub. No.: US 2012/0256069 A1
(43) Pub. Date: Oct. 11, 2012

(54) Adjustable Support Bracket

(75) Inventor: Simon Fallows, Cambridge (CA)

(73) Assignee: MEDIAMOUNTS. LTD., Cambridge (CA)

(21) Appl. No.: 13/080,069

(22) Filed: Apr. 5, 2011

(51) Int. Cl. H05K 7/14; F16M 13/00

(52) U.S. Cl. 248/295.11

(57) ABSTRACT

A height-adjustable support system, comprising a vertically elongated mounting bracket adapted to be attached to a support surface and said mounting bracket including a vertically elongated support track having a top end and a bottom end and a plurality of parallel channels extending between said top end and said bottom end and a carriage assembly having a support surface and channel engaging members wherein said carriage assembly is adapted to be retained by said channels and slide along said channels and said carriage assembly including a support plate adapted to support a computer monitor and said carriage assembly further including a keyboard support and an actuator assembly being operable to releasably retain said carriage assembly in a fixed position relative to said support track.

### FIELD OF THE INVENTION

The present invention relates to a support apparatus and more particularly an adjustable support bracket for height adjustably supporting a display device and input apparatus.

### BACKGROUND OF THE INVENTION

In order to maximize accurate and convenient data input and retrieval, it has become common for industries and particularly the hospital industry to have computer terminals located at various locations throughout the building instead of a dedicated office or desk. These locations include hallways and patient rooms as well as offices so that these terminals or workstations can be used by various individuals on different shifts. Few, if any of the workstations are dedicated to an individual user. Therefore, instead of having office space dedicated to a single user and workstation, the workstations are placed where they are accessible by staff as needed and are usually accessed from a standing position.

Therefore it is important to have a workstation that does not take up much space and accommodates frequent use for short periods at a time. Furthermore, since users come in a variety of heights, it is necessary that the support bracket for the workstation be vertically adjustable. It is also desirable that the workstation when not in use takes up as little space as possible and can be retracted to avoid being bumped by carts or passersby. The invention as described herein addresses these issues and provides advantageous solutions.

### OBJECTS AND SUMMARY OF THE INVENTION

One object of the invention is to provide a mounting bracket for a supporting a monitor and a keyboard.

Another object of the invention is to provide mounting bracket having a track for attachment to a vertical wall or post.

Yet another object of the invention is to provide a height-adjustable monitor support for slidably engaging the track.

Still another object of the invention is to provide mounting bracket having a keyboard support.

Yet another object of the invention is to provide an autoflip rotatable keyboard support.

It must be understood that no one embodiment of the present invention need include all of the aforementioned objects of the present invention. Rather, a given embodiment may include one or none of the aforementioned objects. Accordingly, these objects are not to be used to limit the scope of the claims of the present invention.

In summary the present invention is directed to an adjustable support member for mounting a device, comprising a vertically elongated support track having a top end and a bottom end and a plurality of parallel channels extending between said top end and said bottom end and a carriage assembly having a support surface and channel engaging members wherein said carriage assembly is adapted to be retained by said channels and slide along said channels and an actuator assembly being operable to releasably retain said carriage assembly in a fixed position relative to said support track.

The present invention is further directed to a height-adjustable support system, comprising a vertically elongated mounting bracket adapted to be attached to a support surface and said mounting bracket including a vertically elongated support track having a top end and a bottom end and a plurality of parallel channels extending between said top end and said bottom end and a carriage assembly having a support surface and channel engaging members wherein said carriage assembly is adapted to be retained by said channels and slide along said channels and said carriage assembly including a support plate adapted to support a computer monitor and said carriage assembly further including a keyboard support and an actuator assembly being operable to releasably retain said carriage assembly in a fixed position relative to said support track.

The present invention is further directed to a spring-biased keyboard support, comprising a substantially flat keyboard support surface and a spring-biased hinge connected to said keyboard support surface and to a second support surface whereby said spring-biased hinge operates to automatically flip said keyboard support surface upright.

### BRIEF DESCRIPTION OF THE DRAWINGS

FIG. 1 is a perspective view of the adjustable support bracket;

FIG. 2 is an exploded view of the adjustable support bracket of FIG. 1;

FIG. 3 is a rear perspective view of the track extrusion;

FIG. 4 is a front perspective view of the track extrusion;

FIG. 5 is a top view of the track extrusion of FIGS. 3 and 4;

FIG. 6 is a rear perspective view of the carriage assembly;

FIG. 7 is a perspective view of the actuator assembly;

FIG. 8 is enlarged view of the actuator trigger block of FIG. 7;

FIG. 9 is an enlarged view of the actuator chassis of FIG. 7;

FIG. 10 is a perspective view of the actuator trigger;

FIG. 11 is a perspective view of the lever;

FIG. 12 is a perspective view of the autoflip keyboard support; and,

FIG. 13 is an exploded view of the autoflip keyboard support of FIG. 12.

### DETAILED DESCRIPTION OF THE PREFERRED EMBODIMENT

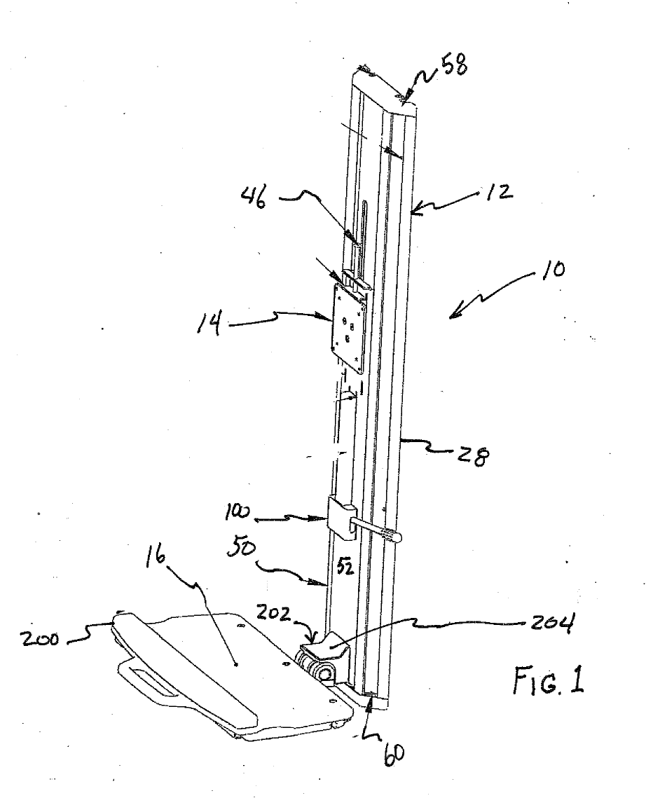

The preferred forms of the invention will now be described with reference to FIGS. 1-13. The appended claims are not limited to the preferred forms and no term and/or phrase used herein is to be given a meaning other than its ordinary meaning unless it is expressly stated otherwise.

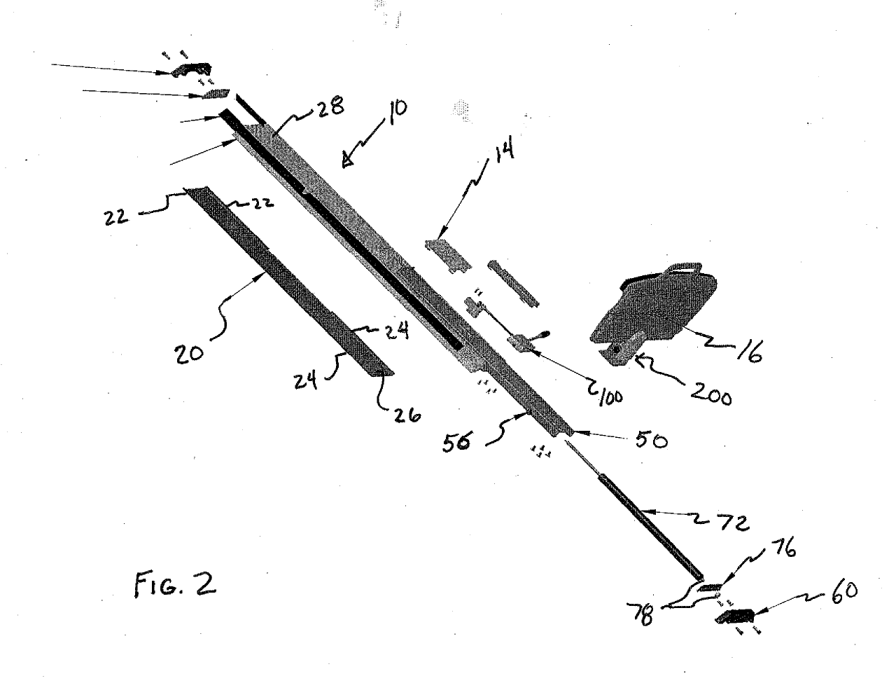

In FIG. 1, a mount 10 is shown having an elongated vertical section 12 having a plate 14 for attachment to a computer monitor or the like (not shown) and a horizontally extending surface 16 suitable for supporting a computer keyboard (also not shown). Now with reference the exploded view of FIG. 2, the mount 10 includes a wallmount plate 20 which is designed to be fixedly secured by conventional fasteners to a vertical surface such as a wall or post. The wallmount plate 20 is preferably formed of substantially rigid material, preferably aluminum and is generally flat. The wallmount plate 20 includes pairs of upper and lower flanges 22 and 24 extending outwardly from the main body 26.

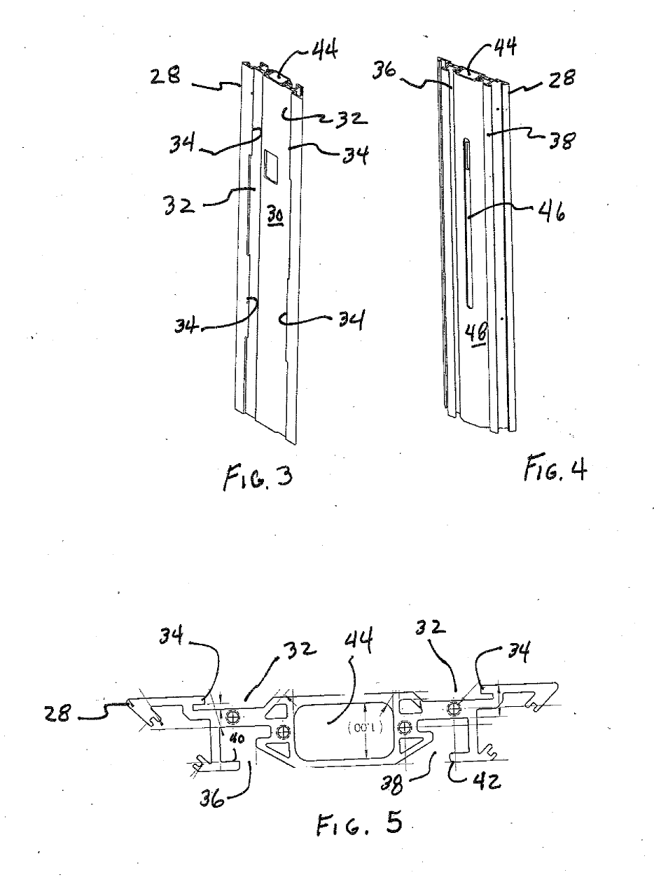

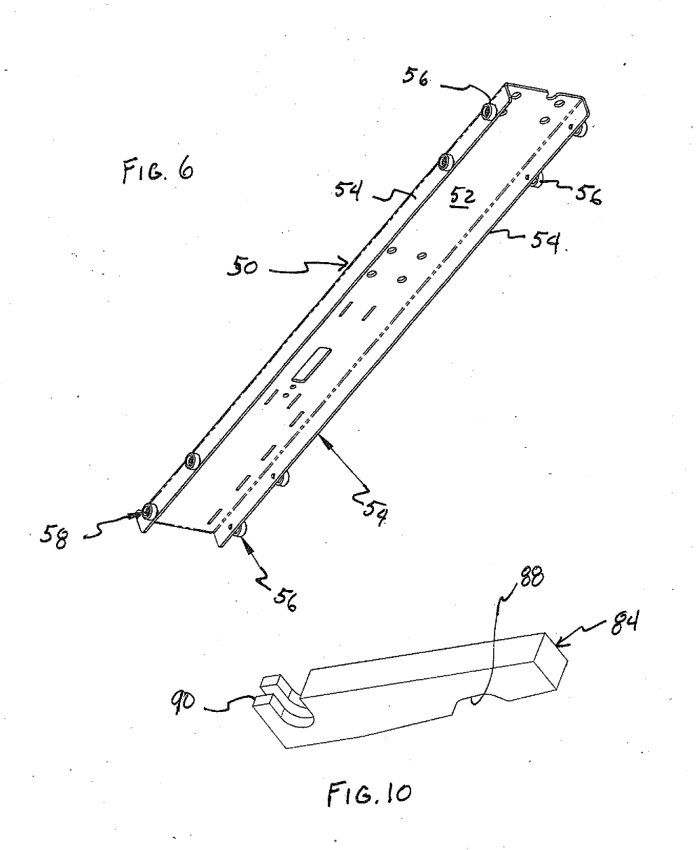

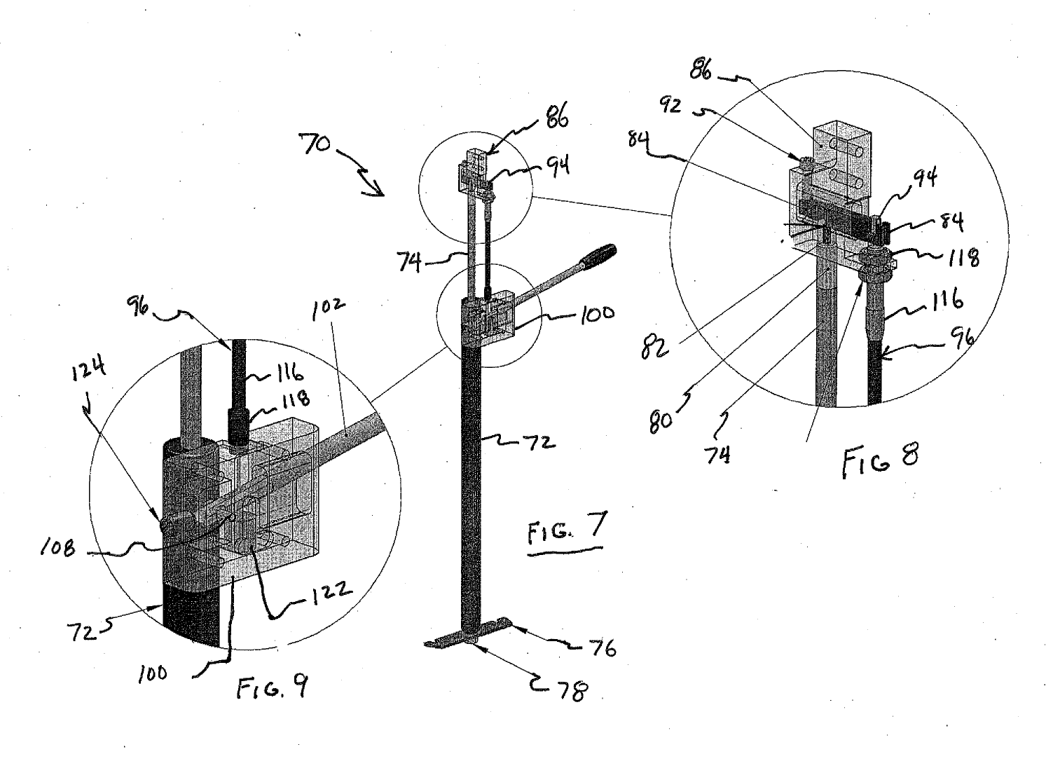

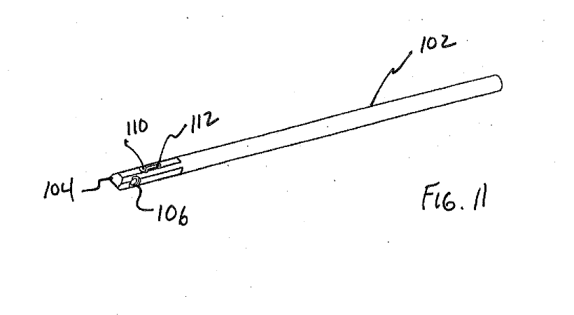

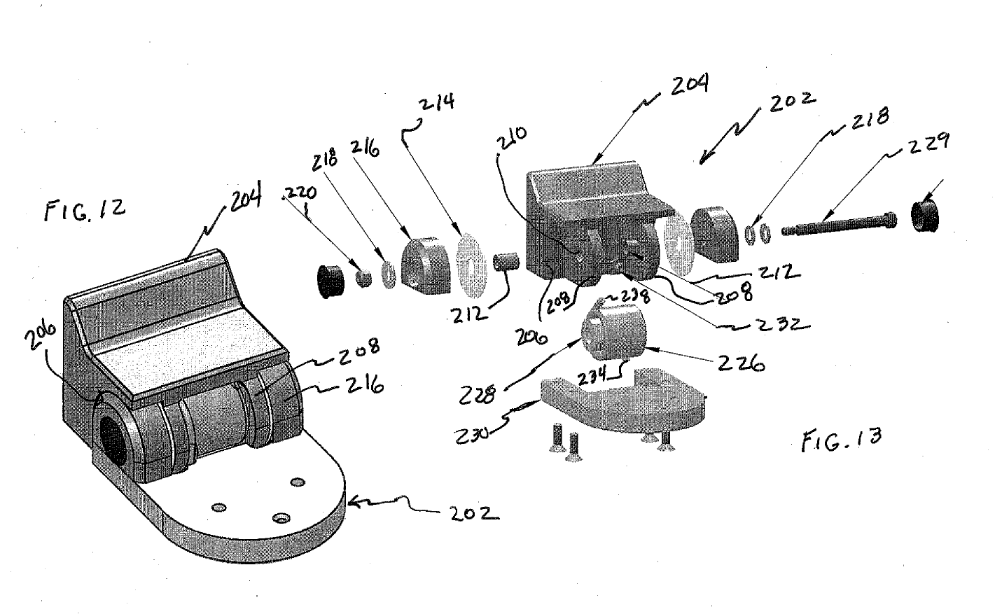

A track extrusion 28 formed of rigid material and preferably aluminum is shown in FIGS. 1, 2, 3, 4 and 5. Looking at the rear wall 30 of the track extrusion 28 in FIG. 3, a pair of recesses 32 are formed and extend the length of the extrusion 28. Four flanges 34 extend from the recesses 32 and engage wall mount flanges 22 and 24 when the track extrusion 28 is connected to the wall mount plate 20. Track extrusion 28 as seen in FIG. 4 includes a pair of channels 36 and 38 extending vertically preferably the entire length of track extrusion 28. As shown in FIG. 5, channels 36 and 38 each include a slot-forming flange or rail 40, 42 respectively. Track extrusion 28 also includes a central tube 44 extending the length of the track extrusion 28. A slot 46 is formed on front wall 48.

A carriage assembly 50 is moveably mounted to the track extrusion 28. As shown in FIGS. 1, 2, and 6, carriage assembly 50 includes a generally elongated front flat surface 52 and carriage roller wheel supporting strips 54 on each side of the front flat surface 52. The carriage roller wheels 56 are retained on the supporting strips 54 by shoulder bolts 58.

The carriage assembly 50 is mounted to the track extrusion 28 by inserting roller wheels 56 into channels 36 and 38. The roller wheels are then retained in channels 36 and 38 by flanges 40 and 42 respectively, but are free to roll within the channels.

A pair of end caps 58 and 60 join the wallmount plate 20 and the track extrusion 28 together and keep them from sliding relative to each other. End caps 58 and 60 also provide stops for the carriage assembly 50 and keep it from rolling out of the channels 36 and 38.

Now the actuator assembly 70 will be described with respect to FIGS. 1, 2, 7, 8 and 9. The actuator assembly 70 preferably includes a gas spring cylinder 72 having a gas spring rod 74. The gas spring cylinder 72 is mounted to a footing plate 76 preferably by a threaded fastener assembly 78. The footing plate 76 is attached at the foot 78 of the track extrusion 28 and is covered by end cap 60. The gas spring cylinder 72 extends into the central tube 44 of the track extrusion.

At the top 80 of the gas spring rod is a valve 82 which allows air into and out of the gas spring cylinder 72. Operation of the valve 82 is accomplished by movement of an actuator trigger 84 held within the actuator trigger block 86. The actuator trigger block 86 is connected by conventional screws to the flat front surface 52 of the carriage assembly 50. The actuator trigger 84 as shown in FIG. 10 is generally rectangular and has a recess 88 on the bottom thereof and a U-shaped forked slot 90 on one end. The recess 88 engages the valve 82 to limit airflow and when the trigger 84 is released air is allowed to flow into or out of the valve 82. A trigger pivot screw 92 is provided to adjust the degree of movement of the trigger 84. The U-shaped forked slot 90 receives the top end 94 of pull cable 96. Pull cable 96 extends downwardly from the trigger block 86 to actuator lever chassis 100.

Actuator chassis 100 includes a lever 102. Lever 102 as shown in FIG. 10 includes a chiseled end 104. Spaced from chiseled end 104 is a horizontal opening 106 for receiving a pivot pin 108. Pivot pin 108 is fixed to the actuator chassis 100 and retains the lever 102 within the chassis 100. Spaced from horizontal opening 106 is a round vertical opening 110 having a slot 112 extending along the lever 102 away from chiseled end 104. Opening 110 and slot 112 are adapted to receive and retain the second end 114 of the pull cable 96. Pull cable 96 includes an outer housing 116 which includes upper fasteners 118 and lower fastener 120 to connect the housing 116 to the trigger block 86 and the actuator chassis 100. A compression spring 122 is located within the actuator chassis 100 and operates to bias the lever 102 upwardly. A plunger screw 124 operates to engage the chiseled end 104 of the lever 102 to limit movement of the lever 102. When the plunger screw 124 is backed off, the lever 102 is free to rotate.

Now with reference to FIGS. 1, 2, 12 and 13 the auto flip keyboard support assembly will be described. Preferably at the flat front surface 52 of the carriage assembly 50, a keyboard support assembly 200 is mounted. The keyboard support 200 is attached to an auto flip chassis 202 having a base member 204 for attachment to the flat front surface 52. The base member 204 includes an arcuate base wall 206 having a pair of spaced apart circular flanges 208 extending therefrom. Each of the flanges 208 includes a central opening 210 for receiving preferably a brass bushing 212. On each outer side of the circular flanges 208 are preferably fastened a nylon washer 214, a pivot lobe 216, an SAE washer 218, a nylock nut 220 and a pair of bore caps 224. Located between the circular flanges 208 is a torsion spring 226 and an alignment bushing 228. A shoulder bolt 229 connects to the nylock nut 220 to hold the parts together. A keyboard attachment plate 230 is preferably screwed to the pivot lobes 216. A set screw 232 is attached to the base member 204 and engages an arm 234 of the torsion spring 226. The other arm 238 of the torsion spring engages the keyboard plate 230 so that the spring can cause rotation of the keyboard plate 230 relative to the base member. The set screw 232 can be adjusted so that tension on the torsion spring 226 can be increased or decreased.

In operation, the actuator assembly 70 permits vertical adjustment of the plate 14 and the keyboard support assembly 200 in a single handed motion vertically by moving the lever 102 downwardly to which causes pull cable 96 to move actuator trigger 84 and open valve 82 of the gas spring cylinder 72. Once the valve 82 is opened, the carriage assembly 50 can be slid upward or downward. To lock the carriage assembly 50 in a desired position, the lever 102 is simply released and valve 82 is closed by the actuator trigger 84.

It should be understood that the rigid materials used in the manufacture of the mount 10 unless specifically identified can be aluminum or other suitably rigid material such as plastic.

While this invention has been described as having a preferred design, it is understood that the preferred design can be further modified or adapted following in general the principles of the invention and including but not limited to such departures from the present invention as come within the known or customary practice in the art to which the invention pertains. The claims are not limited to the preferred embodiment and have been written to preclude such a narrow construction using the principles of claim differentiation.

I claim:

1. An adjustable support member for mounting a device, comprising:
a) a vertically elongated support track having a top end and a bottom end and a plurality of parallel channels extending between said top end and said bottom end;
b) a carriage assembly having a support surface and channel engaging members wherein said carriage assembly is adapted to be retained by said channels and slide along said channels;
c) an actuator assembly being operable to releasably retain said carriage assembly in a fixed position relative to said support track.

2. The adjustable support member as set forth in claim 1, wherein:
a) said actuator assembly includes a gas spring cylinder having first and second ends;
b) said first end of said gas spring cylinder being fixed to said support track;
c) said second end of said gas spring cylinder being fixed to said carriage assembly;
d) said gas spring cylinder being operable to support said carriage assembly in a fixed position.

3. The adjustable support member as set forth in claim 1, wherein:
a) said carriage assembly includes a keyboard support.

4. The adjustable support member as set forth in claim 1, wherein:
a) said carriage assembly includes a mounting plate.

5. The adjustable support member as set forth in claim 2, wherein:
a) said actuator assembly includes an actuator lever block spaced below an actuator trigger block; and,
b) an actuator cable extends between said actuator trigger block and said actuator lever block.

6. The adjustable support member as set forth in claim 5, wherein:
a) said actuator lever block includes a lever extending outwardly from said block and forming a handle for operating said actuator assembly.

7. The adjustable support member as set forth in claim 5, wherein:
a) said actuator trigger block includes a trigger;
b) said gas spring cylinder includes an air valve; and,
c) said actuator trigger is operable to open and close said air valve.

8. The adjustable support member as set forth in claim 7, wherein:
a) said actuator lever is connected to a first end of said actuator cable and said actuator trigger is connected to a second end of said actuator cable.

9. The adjustable support member as set forth in claim 8, wherein:
a) an outer housing surrounds a portion of said actuator cable; and,
b) said outer housing includes a first connector for connection to said actuator trigger block and a second connector for connection to said actuator lever block.

10. The adjustable support member as set forth in claim 3, wherein:
a) said keyboard support is hingedly mounted to said carriage assembly.

11. The adjustable support member as set forth in claim 10, wherein:
a) said keyboard support is spring biased to fold upward when not in use.

12. The adjustable support member as set forth in claim 1, wherein:
a) said carriage assembly includes rollers configured to engage said channels.

13. A height-adjustable support system, comprising;
a) a vertically elongated mounting bracket adapted to be attached to a support surface;
b) said mounting bracket including a vertically elongated support track having a top end and a bottom end and a plurality of parallel channels extending between said top end and said bottom end;
c) a carriage assembly having a support surface and channel engaging members wherein said carriage assembly is adapted to be retained by said channels and slide along said channels;
d) said carriage assembly including a support plate adapted to support a computer monitor;
e) said carriage assembly further including a keyboard support;
f) an actuator assembly being operable to releasably retain said carriage assembly in a fixed position relative to said support track.

14. The height-adjustable support system, as set forth in claim 13, wherein:
a) said actuator assembly includes a gas cylinder having first and second ends;
b) said first end of said gas cylinder being fixed to said support track;
c) said second end of said gas cylinder being fixed to said carriage assembly;
d) said gas cylinder being operable to support said carriage assembly in a fixed position.

15. The height-adjustable support system, as set forth in claim 14, wherein:
a) said gas cylinder is a spring operated gas cylinder.

16. The height-adjustable support system, as set forth in claim 13, wherein:
a) said actuator assembly includes an actuator lever block spaced below an actuator trigger block; and,
b) an actuator cable extends between said actuator trigger block and said actuator lever block.

17. The height-adjustable support system, as set forth in claim 16, wherein:
a) said actuator lever block includes a lever extending outwardly from said block and forming a handle for operating said actuator assembly.

18. The height-adjustable support system, as set forth in claim 13, wherein:
a) said actuator trigger block includes a trigger;
b) said gas cylinder includes an air valve; and,
c) said actuator trigger is operable to open and close said air valve.

19. A spring-biased keyboard support, comprising;
a) a substantially flat keyboard support surface;
b) a spring-biased hinge connected to said keyboard support surface and to a second support surface;
c) whereby said spring-biased hinge operates to automatically flip said keyboard support surface upright.

20. The spring-biased keyboard support of claim 19, further comprising:
a) an adjustable set screw for adjusting tension of said spring-biased hinge.
